(19) United States
(12) Patent Application Publication
(10) Pub. No.: US 2010/0025749 A1
(43) Pub. Date: Feb. 4, 2010

(54) SEMICONDUCTOR DEVICE

(75) Inventors: Jong-Ryeol Yoo, Gyeonggi-do (KR); Tai-Su Park, Gyeonggi-do (KR); Jong-Hoon Kang, Gyeonggi-do (KR); Dong-Chan Kim, Gyeonggi-do (KR); Jeong-Do Ryu, Seoul (KR); Seong-Hoon Jeong, Gyeongsangnam-do (KR); Si-Young Choi, Gyeonggi-do (KR); Yu-Gyun Shin, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/534,422

(22) Filed: Aug. 3, 2009

(30) Foreign Application Priority Data
Aug. 1, 2008 (KR) 2008-75638

(51) Int. Cl. H01L 27/10; H01L 27/092

(52) U.S. Cl. 257/306; 257/369; 257/382; 257/E27.062; 257/E27.071

(57) ABSTRACT

A semiconductor device may include an isolation layer, gate electrodes, an insulating interlayer, an impurity region, a capping layer and a plug. The isolation layer may be formed in the substrate. The gate electrodes may be formed on the substrate. The insulating interlayer may be formed on the gate electrodes. The insulating interlayer may have a contact hole between the gate electrodes. The impurity region may be in the substrate exposed through the contact hole. The capping layer may be on the impurity region. The plug may be on the capping layer. Thus, the impurities may not be lost from the impurity region. As a result, the device may have improved electrical characteristics and reliability because depletion may not be generated in the electrode layer

### CROSS-REFERENCE TO RELATED APPLICATION

This application claims priority under 35 USC §119 to Korean Patent Application No. 2008-75638, filed on Aug. 1, 2008, in the Korean Intellectual Property Office (KIPO), the contents of which are herein incorporated by reference in their entirety.

### BACKGROUND

1. Field

Example embodiments relate to a semiconductor device and a method of manufacturing the same.

2. Description of the Related Art

Recently, as semiconductor memory devices may have been highly integrated, an area of a unit cell in the semiconductor memory device may be greatly decreased. Thus, a width of a pattern, a depth of a junction in the unit cell may be reduced.

Particularly, impurity regions, which may be in close relation to electrical characteristics of an electrode, may be formed by a plasma doping process rather than an ion implantation process so as to meet the objectives of a fine structure and a shallow junction.

However, the plasma doping process may utilize a plurality of wet cleaning processes for removing a photoresist film and a stacked layer that may be formed in the plasma doping process. About 40% to about 60% of impurities in the impurity region may be removed together with the photoresist film and the stacked layer during the wet cleaning process.

FIGS. 1 to 3 are cross-sectional views illustrating a conventional method of manufacturing a dual polysilicon gate of a CMOS device using a plasma doping process.

Referring to FIGS. 1 to 3, a semiconductor device 10 may have a cell region A and a peripheral region B. Here, in order to form a CMOS circuit, NMOS and PMOS features may be formed simultaneously in peripheral region B. In order to form a PMOS electrode, isolation layers 20 may be formed in the semiconductor substrate 10. An N⁺ type polysilicon layer 40 may be formed on the semiconductor substrate 10. A photoresist pattern 50 configured to expose a portion of the N⁺ type polysilicon layer 40 in a PMOS region may then be formed on the N⁺ type polysilicon layer 40. The exposed portion of the N⁺ type polysilicon layer 40 may be doped with P⁺ impurities' 60 by a plasma doping process to form an impurity region 70. The photoresist pattern 50 may then be removed. A cleaning process may be performed on the N⁺ type polysilicon layer 40 and the impurity region 70. A metal silicide layer 80 and a hard mask layer 90 may be sequentially formed on the N⁺ type polysilicon layer 40 and the impurity region 70 to complete a gate electrode.

Here, the impurities in the impurity region may be partially removed during the process for removing the photoresist pattern and the cleaning process. The impurity region having a low impurity concentration may cause an increase of depletion in the gate electrode to deteriorate the PMOS device, thereby decreasing a driving current of the PMOS device.

Further, shallow highly doped impurity regions may be formed at an upper surface of the semiconductor substrate in proportion to a shallow depth of a junction. The loss of the impurities from the impurity region during the removal process of the photoresist pattern and the cleaning process may cause difficulties in meeting electrical characteristics of the semiconductor device.

### SUMMARY

According to some example embodiments, there is provided a method of manufacturing a semiconductor device. In the method, a gate insulating layer may be formed on a substrate. The substrate may have a first region where an NMOS is formed and a second region where a PMOS is formed. An N type gate electrode may be formed on the gate insulating layer. A first plasma doping process using P type impurities may be performed on a portion of the N type gate electrode in the second region to form an impurity region. A second plasma doping process using a silicon source gas may be performed on the impurity region to form a capping layer, which prevents an effluence of the P type impurities from the impurity region, on the impurity region.

### BRIEF DESCRIPTION OF THE DRAWINGS

Example embodiments will be more clearly understood from the following detailed description taken in conjunction with the accompanying drawings. FIGS. 1 to 51 represent non-limiting, example embodiments as described herein.

FIGS. 1 to 3 are cross-sectional views illustrating a conventional method of manufacturing a semiconductor device;

FIG. 4 is a graph showing a loss difference of impurities between a process with an impurity effluence preventing layer and a process without an impurity effluence preventing layer;

FIGS. 5 to 10 are cross-sectional views illustrating a method of manufacturing a dual CMOS polysilicon gate in accordance with a first example embodiment;

FIGS. 11 to 18 are cross-sectional views illustrating a method of manufacturing a CMOS device in accordance with a second example embodiment;

FIGS. 19 to 33 are cross-sectional views illustrating a method of manufacturing a DRAM device in accordance with a third example embodiment;

FIGS. 34 to 37 are cross-sectional views illustrating a method of manufacturing a flash memory device in accordance with a fourth example embodiment;

FIGS. 38 to 48 are cross-sectional views illustrating a method of manufacturing a vertical transistor in accordance with a fifth example embodiment;

FIG. 49 is a block diagram illustrating a system including the semiconductor device in accordance with a sixth example embodiment;

FIG. 50 is a block diagram illustrating a system including the semiconductor device in accordance with a seventh example embodiment; and

FIG. 51 is a block diagram illustrating a system including the semiconductor device in accordance with an eighth example embodiment.

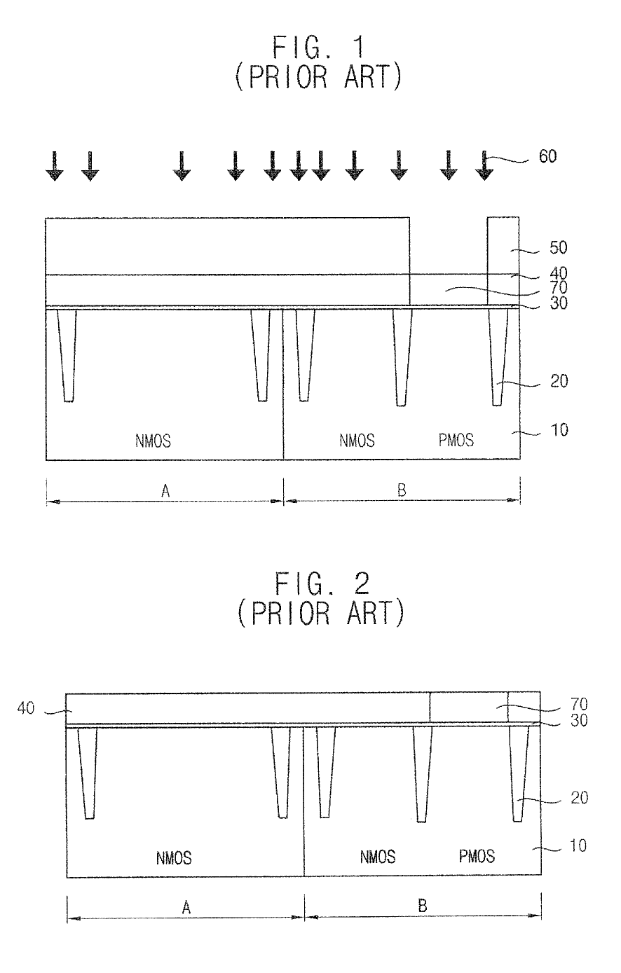

### DETAILED DESCRIPTION OF THE EMBODIMENTS

Various example embodiments will be described more fully hereinafter with reference to the accompanying drawings, in which some example embodiments are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

### Example Embodiment 1

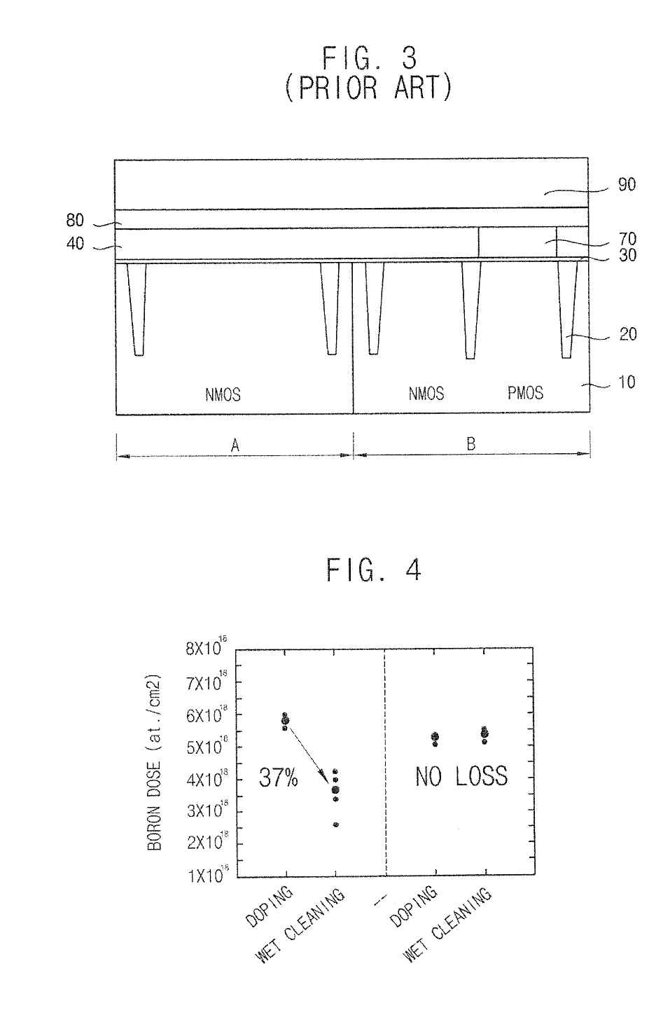

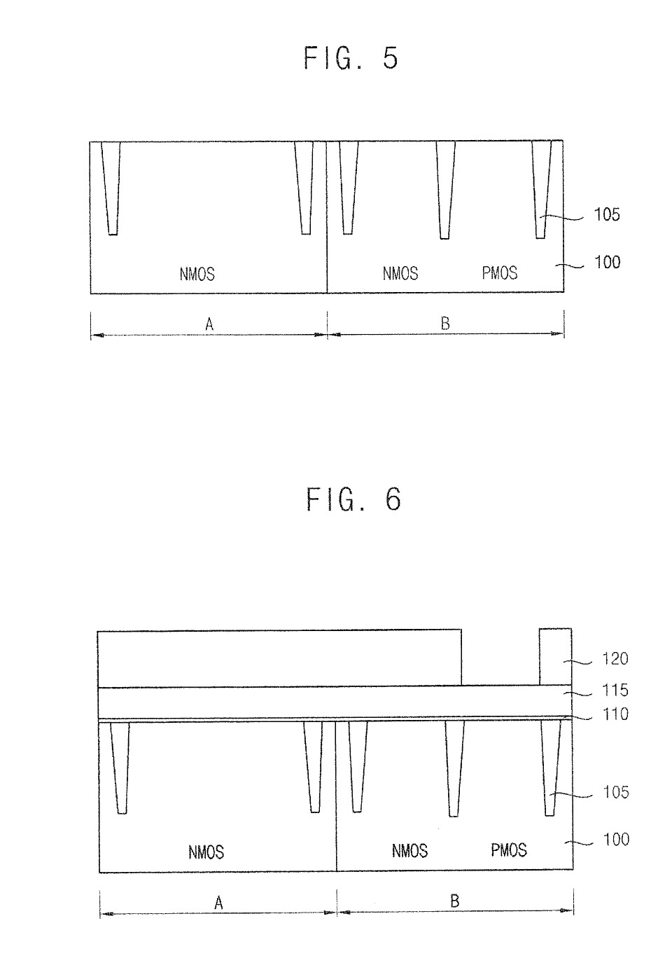

FIG. 4 is a graph showing a loss difference of impurities between a process with an impurity effluence preventing layer and a process without an impurity effluence preventing layer, and FIGS. 5 to 10 are cross-sectional views illustrating a method of manufacturing a dual CMOS polysilicon gate in accordance with a first example embodiment.

Referring to FIG. 4, a plasma doping process may utilize a process for removing a photoresist pattern and a plurality of wet cleaning processes due to a stacked layer that may be formed in the plasma doping process. About 40% to about 60% of impurities in the impurity region may be removed together with the photoresist pattern and the stacked layer during the removal process and the wet cleaning process.

A left region of FIG. 4 may show a loss of about 37% of impurities when the removal process and the cleaning process may be performed without an impurity effluence preventing layer after the plasma doping process.

In contrast, a right region of FIG. 4 may show a reduced loss of impurities when the removal process and the cleaning process may be performed with the impurity effluence preventing layer after the plasma doping process simultaneously with a formation of a capping layer including silicon as the impurity effluence preventing layer.

It may be noted from the right region of FIG. 4 that a dose of the impurities may almost not be changed when the removal process and the cleaning process may be performed after forming the capping layer as the impurity effluence preventing layer. In contrast, it may be noted from the left region of FIG. 4 that performing the cleaning processes may be required, because the stacked layer, which may be formed on a semiconductor substrate during the plasma doping process, may cause a difficulty in removing the photoresist pattern.

Therefore, as shown in the left region of FIG. 4, a great amount of the impurities may be lost during the cleaning processes.

In contrast, as shown in the right region of FIG. 4, when the silicon may be provided to form a thin polysilicon layer on an upper surface of the semiconductor substrate after the plasma doping process, the loss of the impurities may be prevented during the cleaning process.

Thus, this example embodiment may provide the method of manufacturing the semiconductor device that may be capable of constantly maintain the dose of the impurities during the removal process and the cleaning process by forming the capping layer including silicon as the impurity effluence preventing layer simultaneously with the plasma doping process.

Referring to FIG. 5, a semiconductor substrate 100 may have a cell region A and a peripheral region B. In order to constitute a CMOS circuit, an NMOS may be formed in the cell region A, and an NMOS and a PMOS may be formed in the peripheral region.

Isolation layers 105 may be formed in the semiconductor substrate 100. The NMOS in the cell region A may be positioned between the isolation layers 105 in the cell region A. Further, the NMOS and the PMOS in the peripheral region B may be located between the isolation layers 105 in the peripheral region B, respectively. In some example embodiments, the isolation layers 105 may be formed by a shallow trench isolation (STI) process.

Referring to FIG. 6, a gate insulating layer 110 may be formed on the isolation layers 105 and the semiconductor substrate 100. A gate electrode layer 115 may be formed on the gate insulating layer 110. In some example embodiments, the gate insulating layer 105 may have a single layer. Alternatively, the gate insulating layer 105 may have a dual layer so as to form a dual gate.

In some example embodiments, the gate electrode layer 115 may include a polysilicon layer doped with N type impurities.

Here, the gate electrode layer 115 doped with the N type impurities may correspond to an electrode of the NMOS. Further, a portion of the gate electrode layer 115 in a region where the PMOS may be formed may be doped with P type impurities. Thus, a photoresist pattern 120 may be formed on the gate electrode layer 115 to cover first portions of the gate electrode layer 115 where the NMOSs may be formed and expose a second portion of the gate electrode layer 115 where the PMOS may be formed.

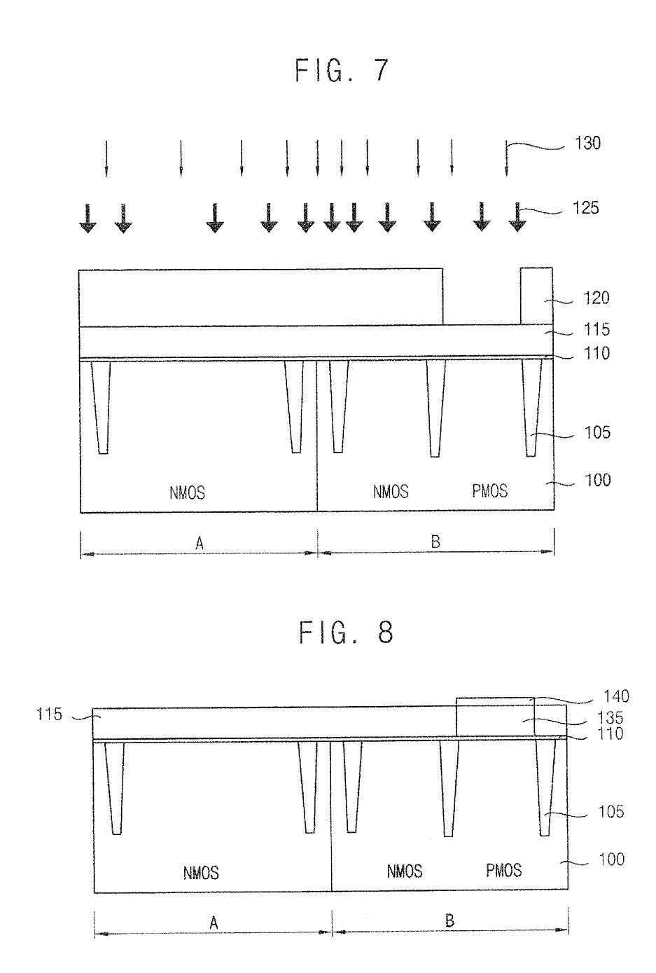

Referring to FIG. 7, the exposed second portion of the gate electrode layer 115 may be doped with P type impurities by a plasma doping process.

In some example embodiments, the plasma doping process may use a source gas including BF₃, B₂H₆, etc.

In some example embodiments, the plasma doping process may include a glow discharge process, a radio frequency (RF) plasma process, a microwave plasma process, etc.

Referring to FIG. 8, as a result of the plasma doping process, a P type impurity region 135 may be formed in the second portion of the gate electrode layer 115. Further, a capping layer 140 may also be formed on the P type impurity region 135 as a result of the plasma doping process. Here, the capping layer 140 may function as an impurity effluence preventing layer.

In some example embodiments, the capping layer 140 may have a surface concentration of the impurities and an inner concentration of the impurities higher than the surface concentration of the impurities. The capping layer 140 may be positioned higher than the semiconductor substrate 100.

The photoresist pattern 120 may then be removed by a stripping process and/or an ashing process. The gate electrode layer 115 may be cleaned by a wet etching process or a dry etching process. Here, the capping layer 140 may prevent a loss of the impurities in the P type impurity region 135 during the removal process and the cleaning process.

After the removal process and the cleaning process, an anneal process may be performed on the semiconductor substrate 100 so as to readily form doping layers. In some example embodiments, the anneal process may include a soak process, a spike process, a laser process, etc.

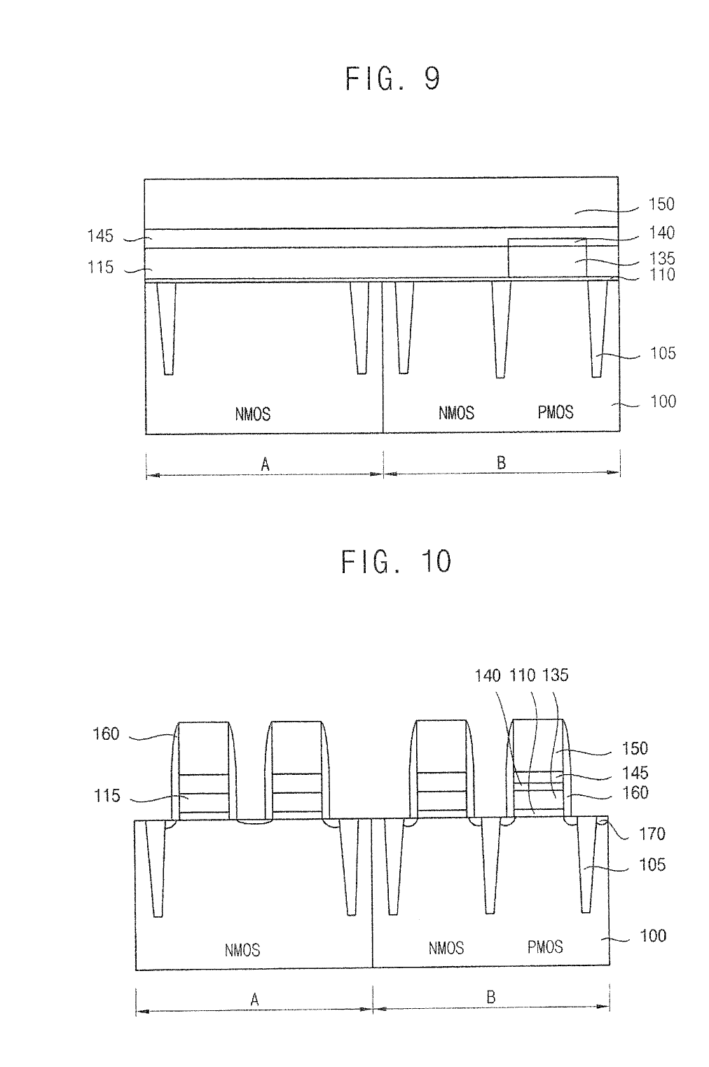

Referring to FIG. 9, a metal silicide layer 145 may be formed on the gate electrode layer 115 and the capping layer 140. A hard mask layer 150 may be formed on the metal silicide layer 145. In some example embodiments, the metal silicide layer 145 may include WSix, WSix/Wn/W, WN/W, TiN/W, WSix/TiN/W, TaN/W, CoSi₂, NiSi, TiSi₂, etc.

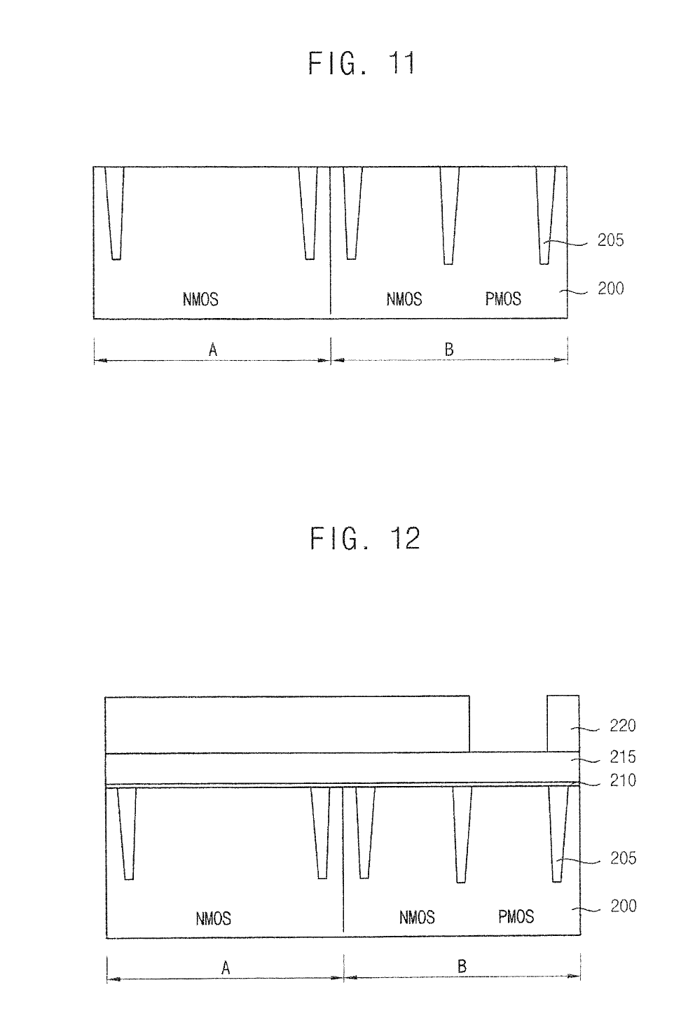

Referring to FIG. 10, the gate electrode layer 115, the P type impurity region 135, the capping layer 140, the metal silicide layer 145 and the hard mask layer 150 may be patterned to form gate structures. Gate spacers 160 may be formed on sidewalls of the gate structures. Impurities may be implanted into the semiconductor substrate 100 using the gate spacers 160 as an ion implantation mask to form heavily doped source/drain regions 170.

As a result, the NMOS and the PMOS of the CMOS device may be completed on the semiconductor substrate 100.

According to this example embodiment, the capping layer may be formed by the plasma doping process using the silicon source gas simultaneously with the formation of the PMOS. The capping layer may prevent the loss of the impurities in the P type impurity region. Therefore, a depletion of the gate electrode may not be generated, so that the CMOS may have a sufficient driving current.

Here, in this example embodiment, after the gate electrode may include the N type impurities, the impurity region of the gate electrode may be doped with the P type impurities. Alternatively, after the gate electrode may include P type impurities, the impurity region of the gate electrode may be doped with N type impurities.

### Example Embodiment 2

FIGS. 11 to 18 are cross-sectional views illustrating a method of manufacturing a CMOS device in accordance with a second example embodiment.

Referring to FIG. 11, a semiconductor substrate 200 may have a cell region A and a peripheral region B. In order to constitute a CMOS circuit, an NMOS may be formed in the cell region A, and an NMOS and a PMOS may be formed in the peripheral region.

Isolation layers 205 may be formed in the semiconductor substrate 200. The NMOS in the cell region A may be positioned between the isolation layers 205 in the cell region A. Further, the NMOS and the PMOS in the peripheral region B may be located between the isolation layers 205 in the peripheral region B, respectively. In some example embodiments, the isolation layers 205 may be formed by a shallow trench isolation (STI) process.

Referring to FIG. 12, a gate insulating layer 210 may be formed on the isolation layers 205 and the semiconductor substrate 200. A gate electrode layer 215 may be formed on the gate insulating layer 210. In some example embodiments, the gate insulating layer 205 may have a single layer. Alternatively, the gate insulating layer 205 may have a dual layer so as to form a dual gate.

In some example embodiments, the gate electrode layer 215 may include a polysilicon layer doped with N type impurities.

Here, the gate electrode layer 215 doped with the N type impurities may correspond to an electrode of the NMOS. Further, a portion of the gate electrode layer 215 in a region where the PMOS may be formed may be doped with P type impurities. Thus, a photoresist pattern 220 may be formed on the gate electrode layer 215 to cover first portions of the gate electrode layer 215 where the NMOSs may be formed and expose a second portion of the gate electrode layer 215 where the PMOS may be formed.

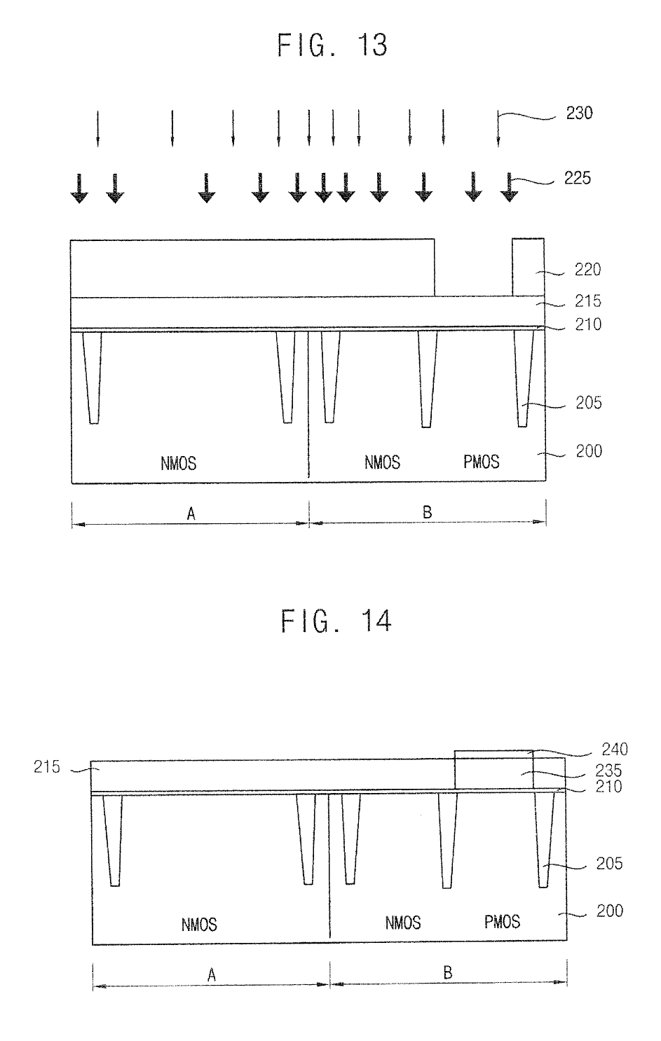

Referring to FIG. 13, the second portion of the gate electrode layer 215 may be doped with P type impurities by a plasma doping process.

In some example embodiments, the plasma doping process may use a source gas including BF₃, B₂H₆, etc.

In some example embodiments, the plasma doping process may include a glow discharge process, a radio frequency (RF) plasma process, a microwave plasma process, etc.

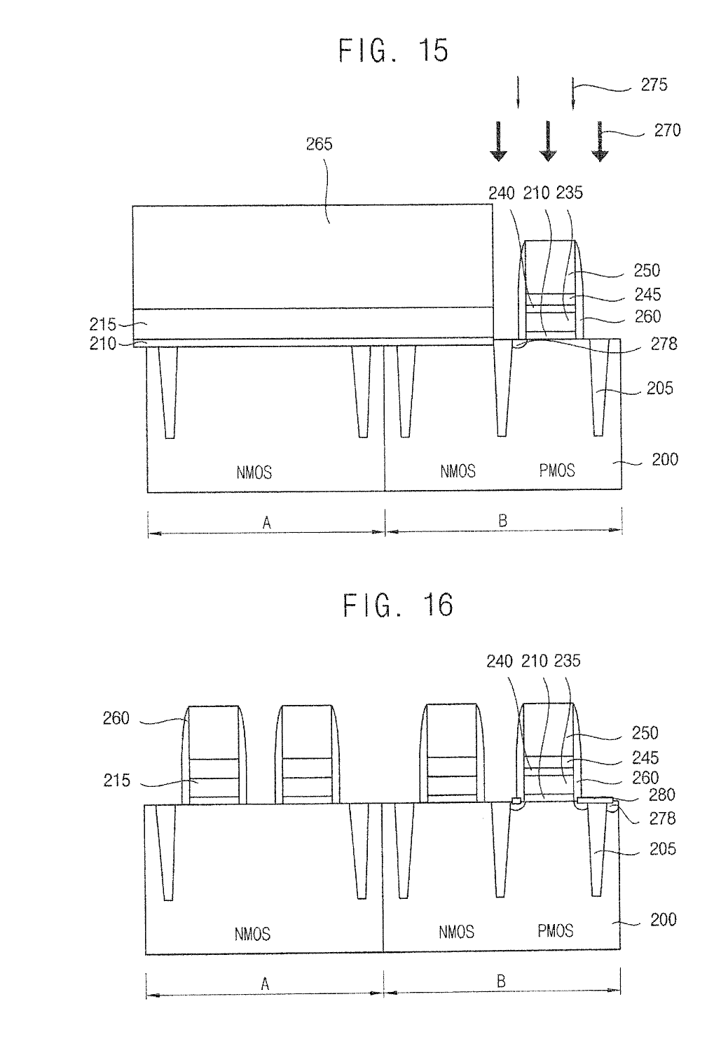

Referring to FIG. 14, after performing the plasma doping process, a P type impurity region 235 may be formed in the second portion of the gate electrode layer 215. Further, a capping layer 240 may be formed on the P type impurity region 235. Here, the capping layer 240 may function as an impurity effluence preventing layer.

In some example embodiments, the capping layer 240 may have a surface concentration of the impurities and an inner concentration of the impurities higher than the surface concentration of the impurities. The capping layer 240 may be positioned higher than the semiconductor substrate 200.

The photoresist pattern 220 may then be removed by a stripping process and/or an ashing process. The gate electrode layer 215 may be cleaned by a wet etching process or a dry etching process. Here, the capping layer 240 may prevent a loss of the impurities in the P type impurity region 235 during the removal process and the cleaning process.

After the removal process and the cleaning process, an anneal process may be performed on the semiconductor substrate 200 so as to readily form doping layers. In some example embodiments, the anneal process may include a soak process, a spike process, a laser process, etc.

Referring to FIG. 15, a metal silicide layer 245 may be formed on the gate electrode layer 215 and the capping layer 240. A hard mask layer 250 may be formed on the metal silicide layer 245. In some example embodiments, the metal silicide layer 245 may include WSix, WSix/Wn/W, WN/W, TiN/W, WSix/TiN/W, TaN/W, CoSi₂, NiSi, TiSi₂, etc.

The gate electrode layer 215, the P type impurity region 235, the capping layer 240, the metal silicide layer 245 and the hard mask layer 250 may be patterned to form gate structures. Gate spacers 260 may be formed on sidewalls of the gate structures.

A photoresist pattern 265 may be formed on the gate electrode layer 215 and the capping layer 240. The photoresist pattern 265 may be configured to cover the regions where the NMOSs may be formed and expose the region where the PMOS may be formed. The region where the PMOS may be formed may be doped with P type impurities 270 by a plasma doping process using the gate structure as an ion implantation mask to form heavily doped source/drain regions 278. In some example embodiments, the plasma doping process may use a source gas including BF₃, B₂H₆, etc.

The region may be doped with a source gas including silicon such as SiH₄, SiCl₂H₂, Si₂Cl₆, Si₂H₆, Si₃H₈, etc, by a plasma doping process. In some example embodiments, the plasma doping process may be performed in a chamber where the plasma doping process for forming the heavily doped source/drain regions 278 may be formed by an in-situ process. Further, the plasma doping process may include a glow discharge process, an RF plasma process, a microwave plasma process, etc.

Referring to FIG. 16, after the plasma doping process, a capping layer 280 may be formed on the heavily doped source/drain regions 278. The capping layer 280 may prevent a loss of the P type impurities in the heavily doped source/drain regions 278 during following removal process and cleaning process.

The photoresist pattern 265 may then be removed by an ashing process and/or a stripping process. The semiconductor substrate 200 may be cleaned.

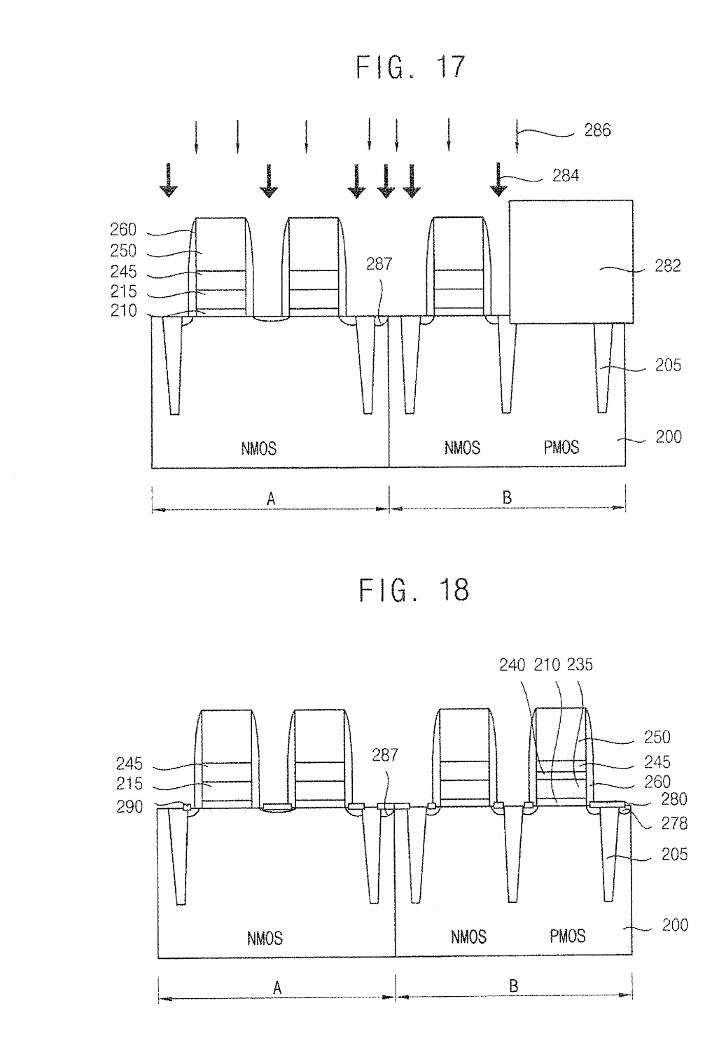

Referring to FIG. 17, a photoresist pattern 282 may be formed on the semiconductor substrate 200. The photoresist pattern 282 may be configured to expose the region where the NMOS may be formed and cover the region where the PMOS may be formed. The region where the NMOS may be formed may be doped with N type impurities 284 by a plasma doping process using the gate structure as an ion implantation mask to form heavily doped source/drain regions 287. In some example embodiments, the plasma doping process may use a source gas including BF₃, B₂H₆, etc.

The region may then be doped with a source gas including silicon such as SiH₄, SiCl₂H₂, Si₂Cl₆, Si₂H₆, Si₃H₈, etc, by a plasma doping process. In some example embodiments, the plasma doping process may be performed in a chamber where the plasma doping process for forming the heavily doped source/drain regions 287 may be formed by an in-situ process. Further, the plasma doping process may include a glow discharge process, an RF plasma process, a microwave plasma process, etc.

Referring to FIG. 18, after the plasma doping process, a capping layer 290 may be formed on the heavily doped source/drain regions 287. The capping layer 290 may prevent a loss of the N type impurities in the heavily doped source/drain regions 287 during following removal process and cleaning process.

In some example embodiments, the capping layer 290 may have a surface concentration of the impurities lower than an impurity concentration in the heavily doped source/drain regions 287. The capping layer 290 may be positioned higher than the semiconductor substrate 200.

The photoresist pattern 282 may then be removed by an ashing process and/or a stripping process. After the removal process and the cleaning process, an anneal process may be performed on the semiconductor substrate 200 so as to readily form doping layers. In some example embodiments, the anneal process may include a soak process, a spike process, a laser process, etc.

In some example embodiments, the capping layers 280 and 290 may include an amorphous polysilicon layer on a single crystalline silicon layer of the semiconductor substrate 200 by a CVD process.

Here, the polysilicon layer having little dose of the impurities in the source/drain regions may have a large area, the source/drain regions may have a high resistance. Thus, the capping layers 280 and 290 can have a thin thickness. Additionally, a silicide layer may be formed on the capping layers 280 and 290 to reduce the resistance of the source/drain regions.

When a nickel silicide layer (not shown) may be formed on the source/drain regions, the source/drain regions may have a very thin thickness and a low resistance.

Therefore, although not depicted in drawings, after performing the process in FIG. 18, the nickel silicide layer may be additionally formed on the capping layers 280 and 290.

As a result, the dual CMOS device including the capping layer 240 on the P type impurity region 235, and the capping layers 280 and 290 on the source/drain regions 278 and 287 may be completed.

According to this example embodiment, the capping layer may be formed by the plasma doping process using the silicon source gas simultaneously with the formation of the PMOS. The capping layer may prevent the loss of the impurities in the P type impurity region. Therefore, a depletion of the gate electrode may not be generated, so that the CMOS may have a sufficient driving current.

### Example Embodiment 3

FIGS. 19 to 33 are cross-sectional views illustrating a method of manufacturing a DRAM device in accordance with a third example embodiment.

Referring to FIG. 19, isolation layers 305 may be formed in a semiconductor substrate 300 to divide the semiconductor substrate 300 into an active region and an inactive region.

In some example embodiments, the isolation layers 305 may be formed by an STI process. For example, the isolation layers 305 may be formed by forming trenches at an upper surface of the semiconductor substrate 300, forming a thermal oxidation layer on the upper surface of the semiconductor substrate 300 and an inner surface of the trenches, forming a nitride layer on the thermal oxidation layer, and filling the trenches with an insulating material by a chemical vapor deposition (CVD) process, a high-density plasma (HDP) CVD process, etc.

A buffer oxide layer 310 may be formed on the semiconductor substrate 300. In some example embodiments, the buffer oxide layer 310 may be formed by a thermal oxidation process. Further, the buffer oxide layer 310 may have a thickness of about 50 Å to about 150 Å.

A hard mask layer 315 may be formed on the buffer oxide layer 310. In some example embodiments, the hard mask layer 315 may include a material having etching rate different from etching rates of the semiconductor substrate 300 and the buffer oxide layer 310. For example, the hard mask layer 315 may include a silicon nitride layer.

A gate mask layer (not shown) may be formed on the hard mask layer 315. In some example embodiments, the gate mask layer may have a multi-layer. For example, the gate mask layer may include a lower layer, a middle layer and an upper layer. The lower layer may include an oxide layer formed by a CVD process. Further, the lower layer may have a thickness of about 2,000 Å to about 3,000 Å. The middle layer may include an organic layer such as an amorphous carbon layer. Further, the middle layer may have a thickness of about 2,000 Å to about 3,000 Å. The upper layer may include an anti-reflective layer such as a nitride layer. Further, the upper layer may have a thickness of about 500 Å. The gate mask layer may be used for forming the hard mask layer 315.

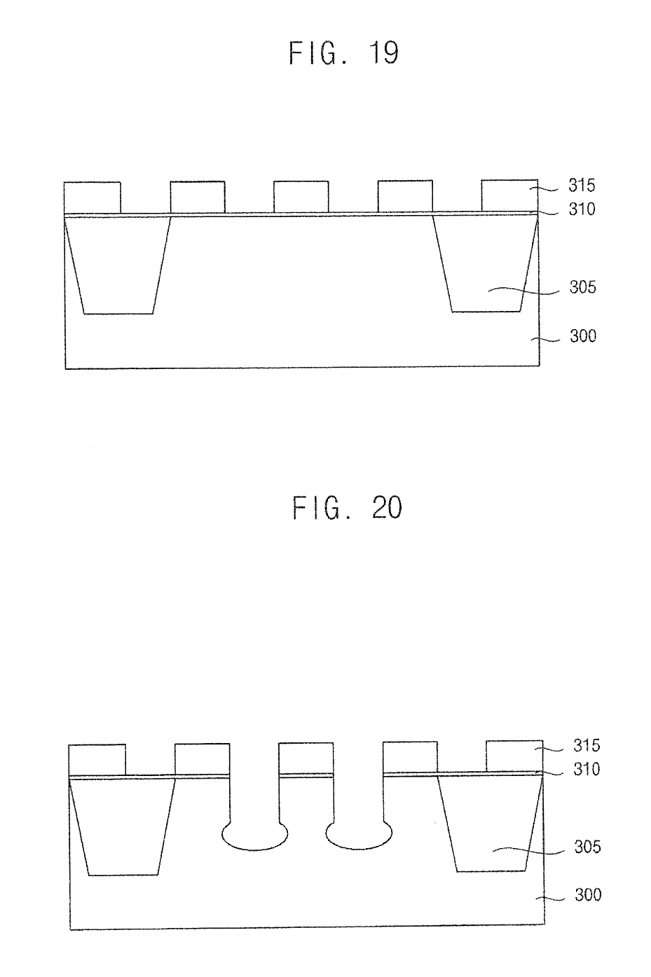

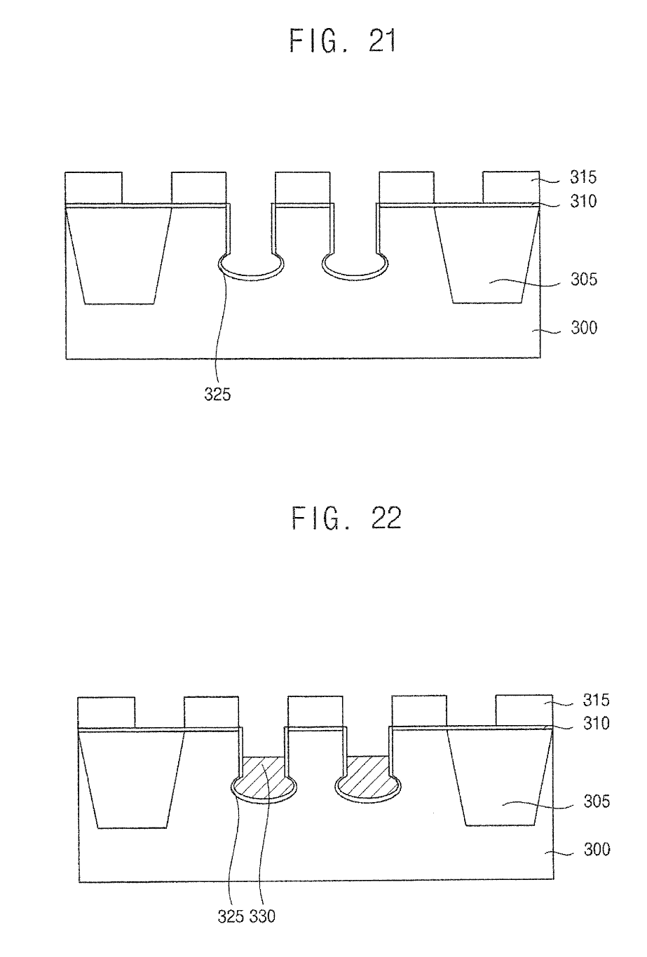

Referring to FIG. 20, the semiconductor substrate 300 in the active region may be etched using the hard mask layer 315 as an etch mask to form preliminary first openings. An etch stop layer (not shown) may be formed on a side surface and a bottom surface of each of the preliminary first openings. In some example embodiments, the etch stop layer may include a nitride layer having a thickness of about 200 Å. An etch-back process may be performed on the etch stop layer to remove a portion of the etch stop layer on the bottom surface of the preliminary first openings. Thus, a portion of the etch stop layer on the side surface may remain.

The bottom surface of the preliminary first openings may be anisotropically etched using the etch stop layer as an etch mask to form first openings having a wide lower portion. That is, the first openings may have an upper width and a lower width greater than the upper width. The etch stop layer may then be removed.

Referring to FIG. 21, a gate insulating layer 325 may be formed on the side surface and the bottom surface of the first openings. In some example embodiments, the gate insulating layer 325 may include a hafnium oxide layer, a tantalum oxide layer, an oxide/nitride/oxide layer, etc.

Referring to FIG. 22, a lower electrode layer 330 may be formed on the gate insulating layer 325 to partially fill the first openings. In some example embodiments, the lower electrode layer 330 may include a polysilicon layer. For example, the first openings may be filled with the polysilicon layer. The polysilicon layer may be partially removed by an etch-back process to form the lower electrode layer 330 in a lower portion of the first openings. Here, an upper portion of the first openings may serve as a space where a spacer may be formed. Thus, because a thickness of the spacer may have influence on a gate induced drain leakage (GIDL) of a device, a thickness of the lower electrode layer 330 may be determined in accordance with the influence. In some example embodiments, the thickness of the lower electrode layer 330 may be about 500 Å to about 1,000 Å.

Here, because the lower portion of the first opening may be larger than the upper portion of the first opening, voids may be generated in the lower electrode layer 330. To prevent the generation of the voids, a heavily doped silicon layer may be formed in the first opening. A lightly doped silicon layer may be formed on the heavily doped silicon layer. The heavily doped silicon layer and the lightly doped silicon layer may be thermally treated to prevent the generation of the voids.

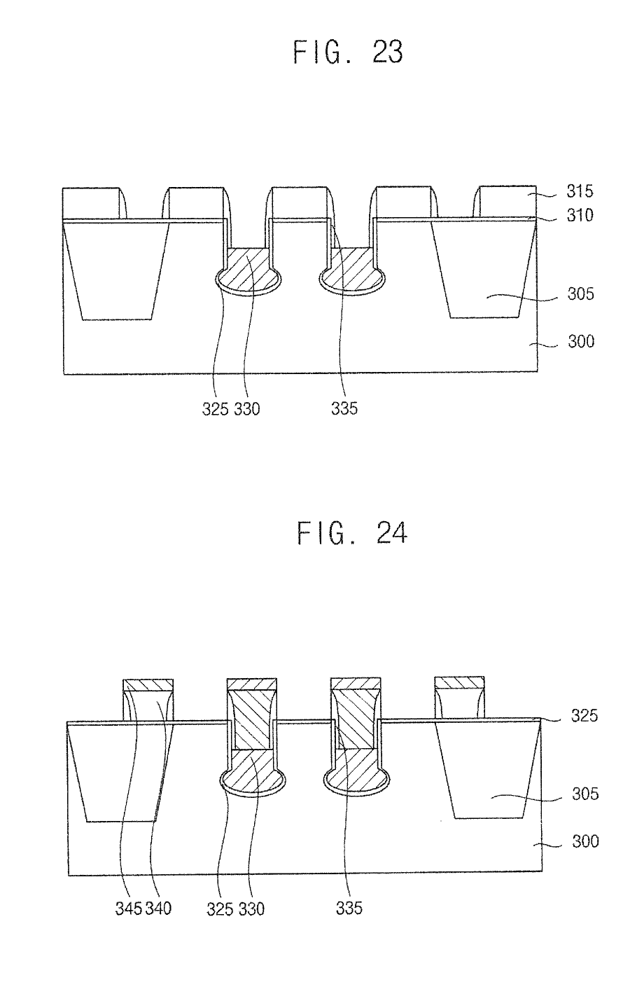

Referring to FIG. 23, an inner spacer 335 may be formed on a sidewall of the hard mask layer 315. Thus, a lower end of the inner spacer 335 may make contact with an edge portion of an upper surface of the lower electrode layer 330. The inner spacer 335 may prevent the GIDL.

Referring to FIG. 24, an upper gate electrode layer 340 may be formed on the lower electrode layer 330 and the inner spacer 335 to fill the first opening. A gate hard mask layer 345 may be formed on the upper gate electrode layer 340. In this example embodiment, the upper gate electrode layer 340 may have a single layer. Additionally, a metal silicide layer (not shown) may be formed on the upper gate electrode layer 340 to reduce a resistance of the upper gate electrode layer 340.

The gate hard mask layer 345 may protect the upper gate electrode layer 340 during following processes. After forming the upper gate electrode layer 340, the hard mask layer 315 may be removed.

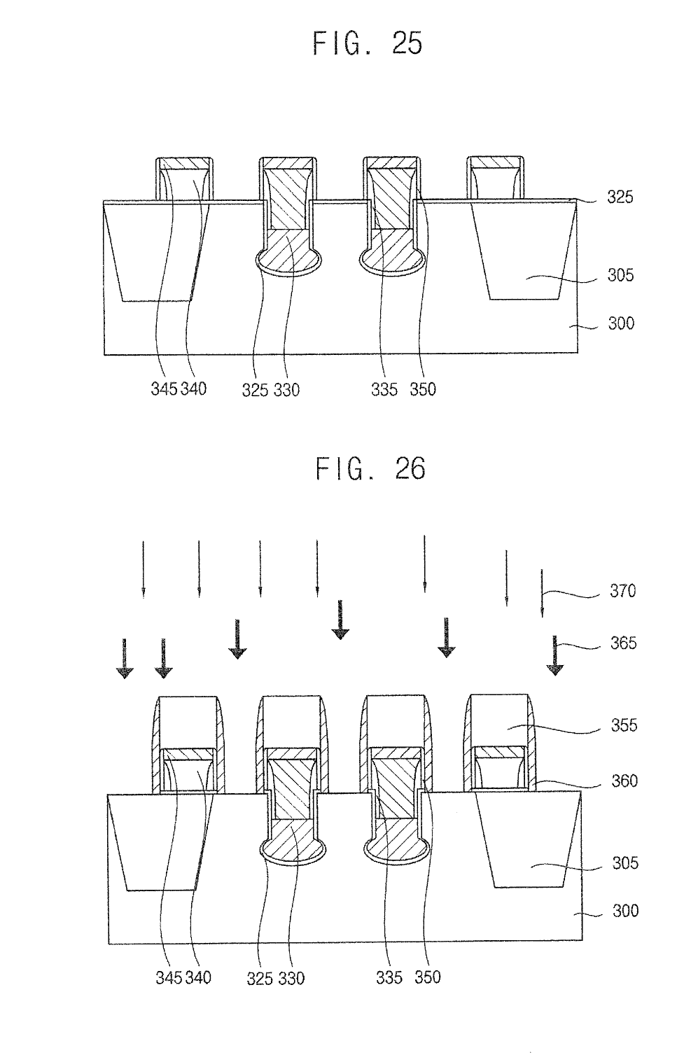

Referring to FIG. 25, the semiconductor substrate 300 may be lightly doped with impurities. An outer spacer 350 may be on sidewalls of the upper gate electrode 340 and the inner spacer 335. The semiconductor substrate 300 may be heavily doped with impurities using the outer spacer 350 as an ion implantation mask to form source/drain regions (not shown).

Referring to FIG. 26, a first insulating interlayer 355 may be formed on the gate hard mask layer 345. In some example embodiments, the first insulating interlayer 355 may include BPSG, PSG, PE-TEOS, HDP-CVD oxide, etc. Further, the first insulating interlayer 355 may be formed by a CVD process, a HDP-CVD process, etc.

In some example embodiments, an insulating layer (not shown) may be formed on the semiconductor substrate 300 to cover the gate hard mask layer 345. A photoresist pattern (not shown) may be formed on the insulating layer. The insulating layer may be etched using the photoresist pattern as an etch mask to form a first contact hole and a second contact hole configured to expose the source/drain regions. Here, a capacitor contact plug may be formed in the first contact hole. A bit line plug may be formed in the second contact hole.

Sidewall spacers 360 may be formed on side surfaces of the contact holes. In some example embodiments, the sidewall spacers 360 may include a nitride layer. The nitride layer may be formed by a CVD process. The nitride layer may be etched to form the sidewall spacers 360.

Portions of the semiconductor substrate 300 exposed through the contact holes may be doped with impurities by a first plasma doping process. Further, the portions of the semiconductor substrate 300 may be doped using a source gas including silicon such as SiH₄, SiCl₂H₂, Si₂Cl₆, Si₂H₆, Si₃Hg, etc, by a second plasma doping process. In some example embodiments, the second plasma doping process may be performed by an in-situ process in a chamber where the first plasma doping process may be performed. Further, the plasma doping process may include a glow discharge process, an RF plasma process, a microwave plasma process, etc.

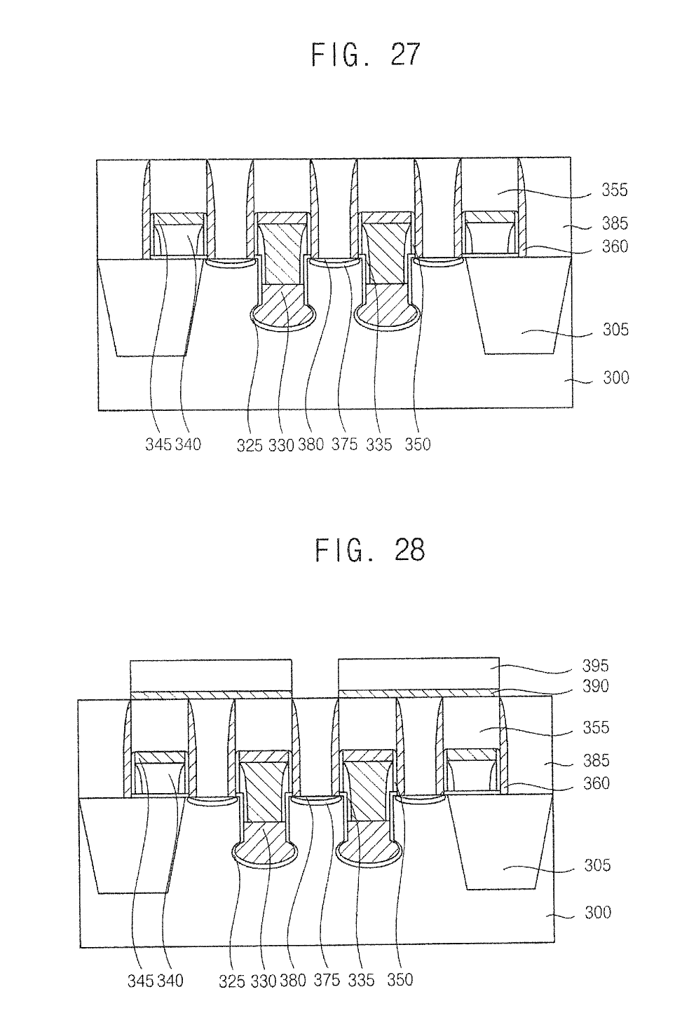

Referring to FIG. 27, after the plasma doping processes, impurity regions 375 may be formed at the upper surface of the semiconductor substrate 300. Further, capping layers 380 as an impurity effluence preventing layer may be formed on the impurity regions 375.

In some example embodiments, the capping layers 380 may include an amorphous polysilicon layer on a single crystalline silicon layer of the semiconductor substrate 300 by a CVD process.

In some example embodiments, the capping layer 380 may have a surface concentration of the impurities and an inner concentration of the impurities higher than the surface concentration of the impurities. The capping layer 380 may be positioned higher than the semiconductor substrate 300.

Here, the polysilicon layer having little dose of the impurities in the impurity regions 375 may have a large area, the impurity regions 375 may have a high resistance. Thus, the capping layers 380 can have a thin thickness. Additionally, a silicide layer may be formed on the capping layers 380 to reduce the resistance of the impurity regions 375.

When a nickel silicide layer (not shown) may be formed on the impurity regions 375, the impurity regions 375 may have a very thin thickness and a low resistance.

The contact holes may then be filled with contact plugs 385. In some example embodiments, the contact plugs 385 may include a capacitor plugs connected with a capacitor, and a bit line plug connected with a bit line. Further, the contact plugs 385 may include a heavily doped polysilicon layer, a metal layer, a conductive metal nitride layer, etc.

Referring to FIG. 28, an etch stop layer 390 and a second insulating interlayer 395 may be sequentially formed on the contact plugs 385 and the first insulating interlayer 355. In some example embodiments, the etch stop layer 390 may include a silicon nitride layer formed by a CVD process. The second insulating interlayer 395 may include BPSG, PSG, PE-TEOS, HDP-CVD oxide, etc., formed by a CVD process, a HDP-CVD process, etc.

A photoresist pattern (not shown) may be formed on the second insulating interlayer 395. The second insulating interlayer 395 may be etched using the photoresist pattern as an etch mask to form bit line contact holes configured to expose the bit line plugs.

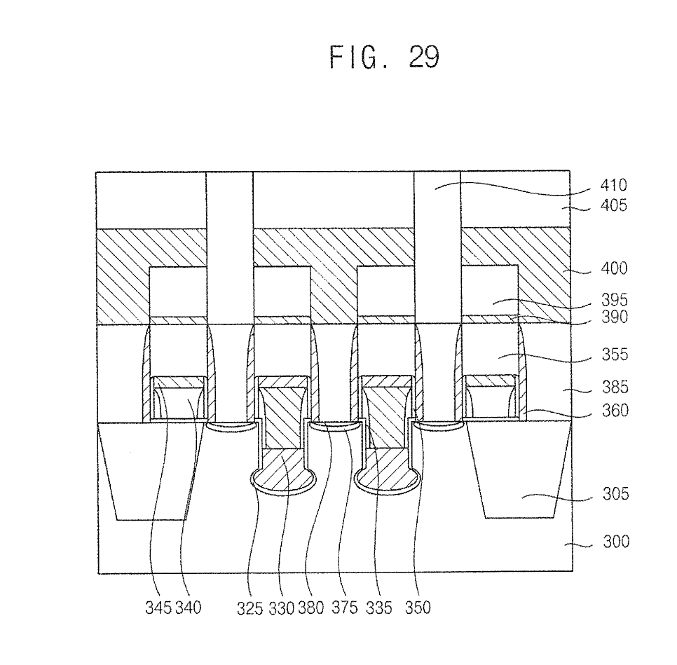

Referring to FIG. 29, a bit line 400 may be formed on the second insulating interlayer 395 to fill up the bit line contact holes.

A third insulating interlayer 405 may be formed on the bit line 400. In some example embodiments, the third insulating interlayer 405 may include BPSG, PSG, PE-TEOS, HDP-CVD oxide, etc., formed by a CVD process, a HDP-CVD process, etc.

A photoresist pattern (not shown) may be formed on the third insulating interlayer 405. The third insulating interlayer 405 may be etched using the photoresist pattern as an etch mask to form a contact hole.

The contact hole may be filled with a capacitor contact pad 410. In some example embodiments, the capacitor contact pad 410 may include a heavily doped polysilicon layer.

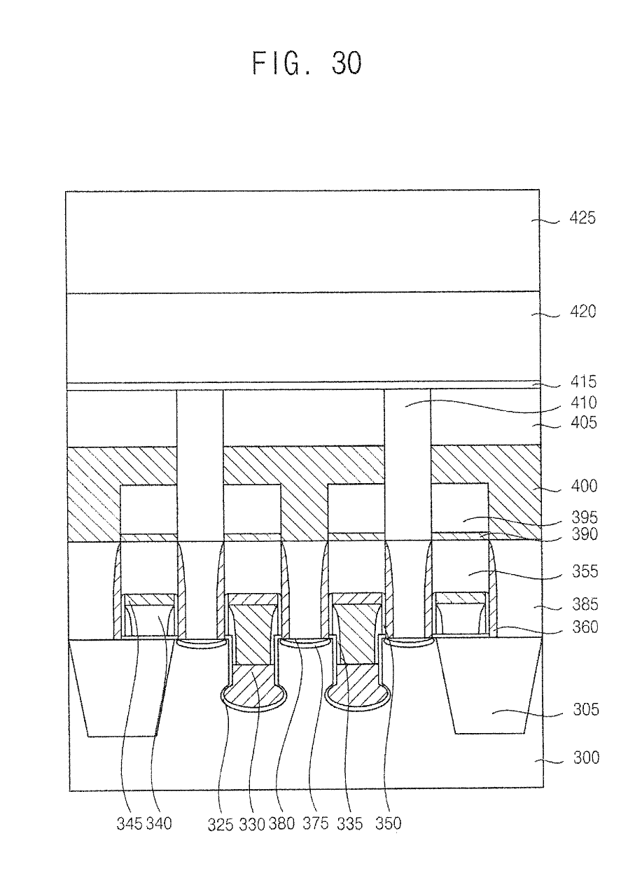

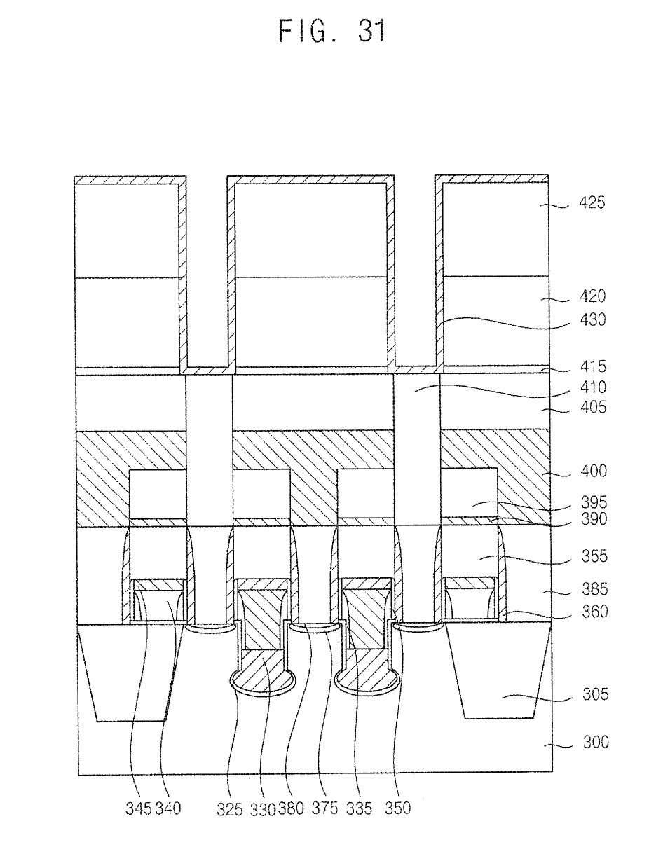

Referring to FIG. 30, an etch stop layer 415 may be formed on the third insulating interlayer 405 and the capacitor contact pad 410. In some example embodiments, the etch stop layer 415 may include a silicon nitride layer formed by a CVD process. A first mold layer 420 and a second mold layer 425 may be sequentially formed on the etch stop layer 415. The first mold layer 420 and the second mold layer 425 may have a total thickness of about 10,000 Å to about 20,000 Å. Further, the first mold layer 420 and the second mold layer 425 may include an oxide layer formed by a CVD process. Alternatively, the first mold layer 420 and the second mold layer 425 may include different materials having different etch ratios for readily forming a hole where a capacitor may be formed.

Referring to FIG. 31, the first mold layer 420 and the second mold layer 425 may be etched using the etch stop layer 415 as an etch endpoint to form openings. In some example embodiments, the openings may be formed by a dry etch process.

Portions of the etch stop layer 415 on the capacitor contact pad 410 may be removed. A lower electrode layer may be formed on an upper surface of the second mold layer 425 and an inner surface of the openings. In some example embodiments, the lower electrode layer may include TiN, Ti, TaN, Pt, etc. Here, the lower electrode layer may have a characteristic capable of closely contacting with the capacitor contact pad 410. Further, the etch stop layer 415 may have a sufficient thickness for supporting the lower electrode layer to prevent the lower electrode layer from being collapsed during removing the mold layers 420 and 425.

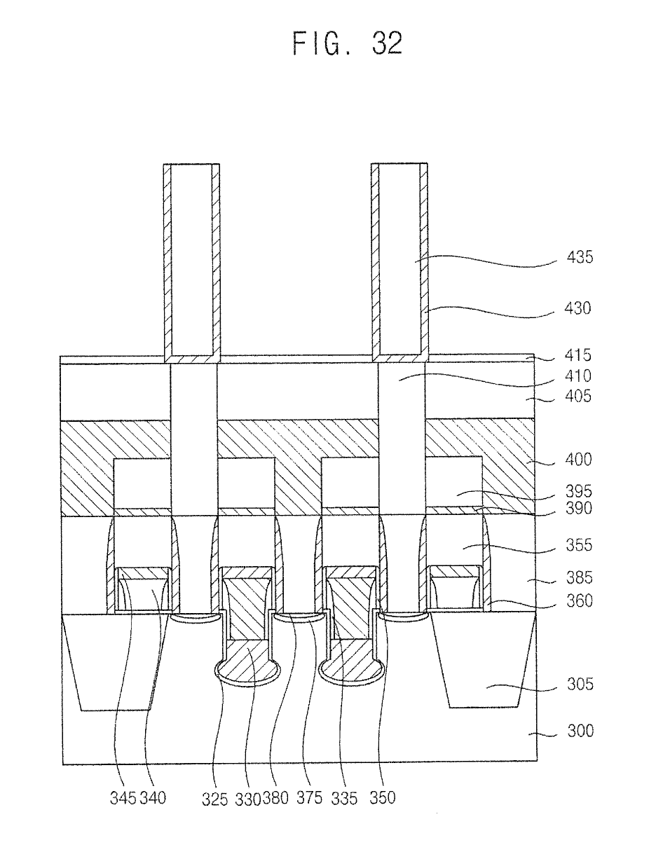

Referring to FIG. 32, a buried layer 435 may be formed on the lower electrode layer. In some example embodiments, the buried layer 435 may have a good gap-filling characteristic such as TOZS. Alternatively, the buried layer 435 may include a material having an etch ratio different from that of the mold layers 420 and 425 such as an organic layer to prevent the collapse of the lower electrode layer.

The buried layer 435 may be planarized by an etch-back process. Simultaneously, upper portions of the lower electrode layer may be removed to form a lower electrode 430. In some example embodiments, the upper portions of the lower electrode may be removed by a wet etch-back process.

Here, when the lower electrode 430 may have a sharp upper end, the sharp upper end may cut a dielectric layer to generate a leakage current. Thus, in order to prevent the upper end of the lower electrode 430 from being sharpened, the lower electrode layer may be wet-etched to provide the upper end of the lower electrode 430 with a round shape.

The mold layers 420 and 525 and the buried layer 435 may be removed by a lift-off process. Here, in the removal process, it may be used to prevent the adjacent lower electrodes 430 from being adhered.

In order to prevent the collapse of the lower electrodes 430, a structure may be provided to the lower electrodes 430. In some example embodiments, the structure may have a ladder shape, an annular shape, etc.

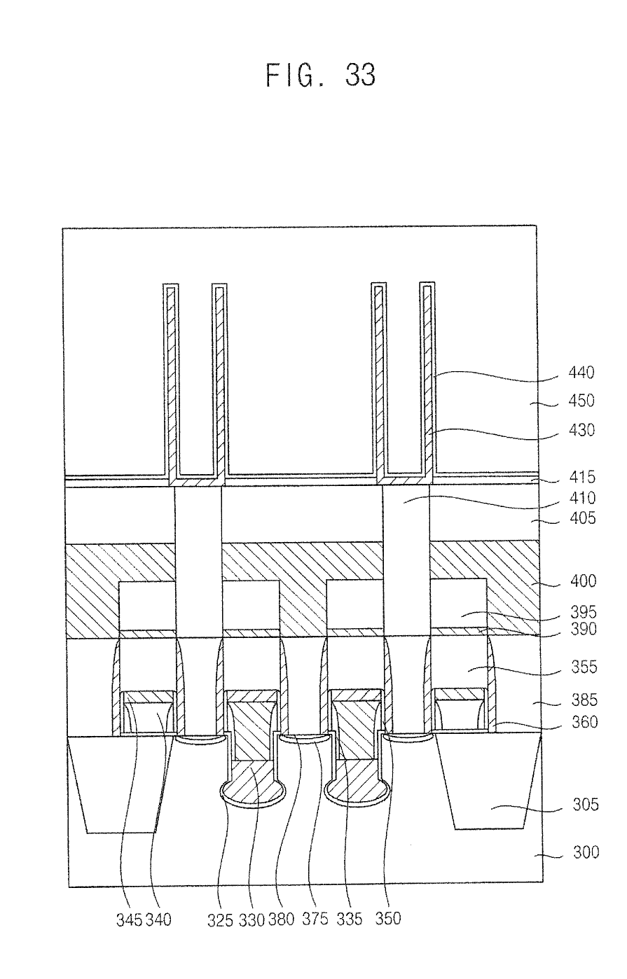

Referring to FIG. 33, a dielectric layer 440 may be formed on the lower electrode layer 430. In some example embodiments, the dielectric layer 440 may include a zirconium oxide layer formed by an atomic layer deposition (ALD) process. For example, a precursor may be applied to the lower electrode 430 in an ALD chamber. The precursor may include tetrakis-ethylmethylamino zirconium (TEMAZ). The precursor may be chemisorbed with the lower electrode 430. A purge gas may be introduced into the chamber to remove non-reacted gases. The purge gas may include an argon gas, a helium gas, a nitrogen gas, etc. When the non-reacted gases may be removed, the chemisorbed layer on the lower electrode 430 may have an atomic thickness. Here, because the chemisorption process may be performed at a low temperature of about 250° C., the chemisorbed layer may be uniformly formed on a capacitor having a high aspect ratio. Further, because an entrance of the cylindrical lower electrode 430 may not be clogged, the precursor may be uniformly distributed on a bottom surface of the cylindrical lower electrode 430. Therefore, the capacitor may have good step coverage.

An oxidizing agent may be introduced into the chamber at a temperature of about 275° C. The oxidizing agent may be reacted with the precursor to form the zirconium oxide layer. The oxidizing agent may include O₂, O₃, H₂O, etc. In this example embodiment, the oxidizing agent may include O₃ having a strong oxidation. Carbon or nitrogen in the precursor may be removed to form the zirconium oxide layer. This cycle may be repeated dozens times to form the zirconium oxide layer having a desired thickness. In this example embodiment, the cycle may be repeated about 100 times to about 150 times to form the zirconium oxide layer having a thickness of about 100 Å to about 150 Å.

Additionally, a zirconium oxynitride layer (not shown) may be formed on the zirconium oxide layer. Thus, the dielectric layer 440 may have a dual layer including the zirconium oxide layer and the zirconium oxynitride layer.

Alternatively, the dielectric layer 440 may include materials having diverse dielectric constants such as ZrO₂/Al₂O₃/ZrO₂ (ZAZ), ZrO₂/Al₂O₃/TaO₂ (ZAT), Hf₂O₃, etc.

An upper electrode 450 may be formed on the dielectric layer 440. In some example embodiments, the upper electrode 450 may include TiN, Ti, TaN, Pt, etc.

Although not depicted in drawings, an insulating layer and a metal wiring may be formed on the upper electrode 450 to form the capacitor without leakage currents. Further, capping layer 380 may prevent the loss of the impurities in the impurity regions, so that the DRAM device may have high capacity.

Moreover, the impurity regions in the contact hole may have a thin thickness, so that the DRAM device may have a readily controllable refresh time.

### Example Embodiment 4

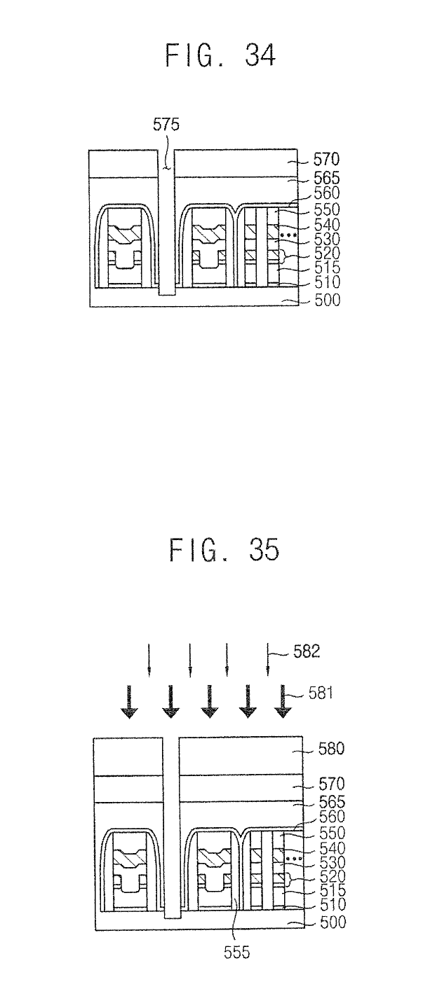

FIGS. 34 to 37 are cross-sectional views illustrating a method of manufacturing a flash memory device in accordance with a fourth example embodiment.

Referring to FIG. 34, a tunnel oxide layer 510 may be formed on a semiconductor substrate 500. The semiconductor substrate 500 may have a cell region and a peripheral region. Flash gate structures may be formed on the tunnel oxide layer 510. The flash gate structure in the cell region may have a string cell structure including a tunnel gate 515, a gate insulating layer 520, control gates 530 and 540 and a hard mask layer 550. In contrast, the flash memory structure in the peripheral region may not have a control gate.

An etch stop layer 560 may be formed on the flash gate structures. A first insulating interlayer 565 and a second insulating interlayer 570 may be sequentially formed on the etch stop layer 560. A contact hole 575 may be formed through the first insulating interlayer 565 and the second insulating interlayer 570.

Referring to FIG. 35, a photoresist pattern 580 may be formed on the second insulating interlayer 570 to expose the contact hole 575. Portions of the semiconductor substrate 500 exposed through the contact holes 575 may be doped with impurities by a first plasma doping process. Further, the portions of the semiconductor substrate 500 may be doped using a source gas including silicon such as SiH₄, SiCl₂H₂, Si₂Cl₆, Si₂H₆, Si₃H₈, etc, by a second plasma doping process. In some example embodiments, the second plasma doping process may be performed by an in-situ process in a chamber where the first plasma doping process may be performed. Further, the plasma doping process may include a glow discharge process, an RF plasma process, a microwave plasma process, etc.

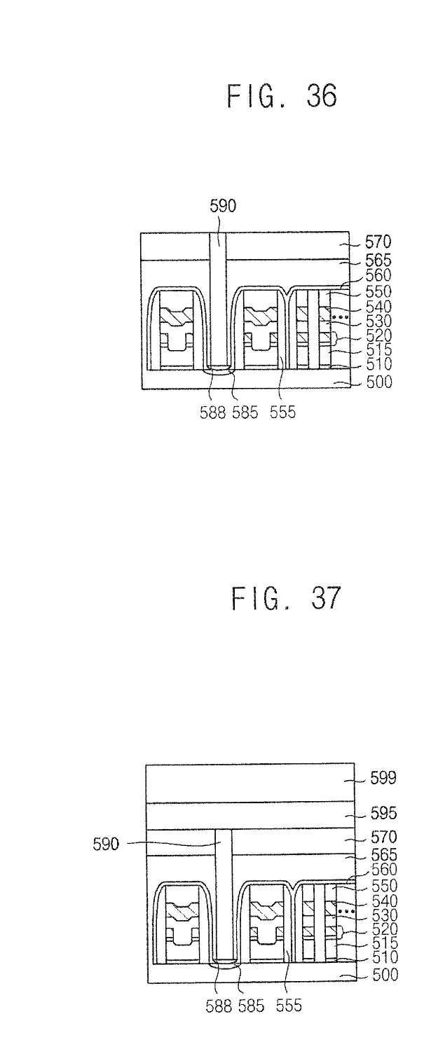

Referring to FIG. 36, after the plasma doping processes, an impurity region 585 may be formed at the upper surface of the semiconductor substrate 500. Further, a capping layer 588 as an impurity effluence preventing layer may be formed on the impurity region 585.

In some example embodiments, the capping layer 588 may include an amorphous polysilicon layer on a single crystalline silicon layer of the semiconductor substrate 500 by a CVD process.

In some example embodiments, the capping layer 588 may have a surface concentration of the impurities and an inner concentration of the impurities higher than the surface concentration of the impurities. The capping layer 588 may be positioned higher than the semiconductor substrate 500.

Here, the polysilicon layer having little dose of the impurities in the impurity region 585 may have a large area, the impurity region 585 may have a high resistance. Thus, the capping layer 588 can be provided with a thin thickness. Additionally, a silicide layer may be formed on the capping layer 588 to reduce the resistance of the impurity region 585.

When a nickel silicide layer (not shown) may be formed on the impurity region 585, the impurity region 585 may have a very thin thickness and a low resistance.

The contact hole 575 may be filled with a contact plug 590. In some example embodiments, the contact plug 590 may be connected with a metal wiring. The contact plug 590 may include a heavily doped polysilicon layer, a metal layer, a conductive metal nitride layer, etc.

Referring to FIG. 37, a metal wiring 595 may be formed on the contact plug 590 and the second insulating interlayer 570. A protecting layer 599 may be formed on the metal wiring 595.

According to this example embodiment, the flash memory device may include the capping layer on the impurity region, so that loss of the impurities in the impurity region may be prevented. As a result, the flash memory device may have improved electrical characteristics.

### Example Embodiment 5

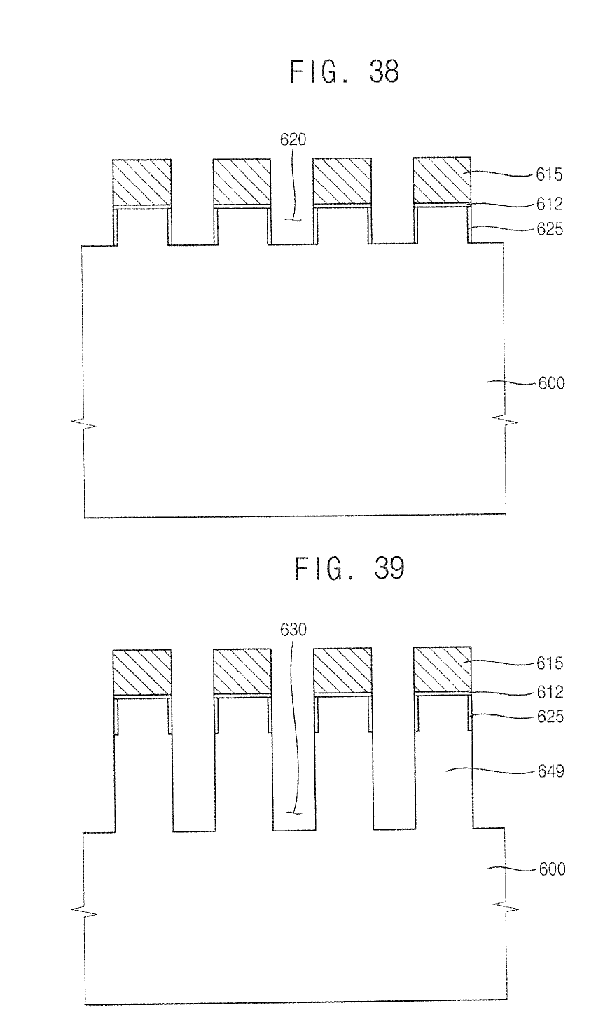

FIGS. 38 to 48 are cross-sectional views illustrating a method of manufacturing a vertical transistor in accordance with a fifth example embodiment.

Referring to FIG. 38, a pad oxide layer 612 may be formed on a semiconductor substrate 600. A hard mask layer 615 may be formed on the pad oxide layer 612. The semiconductor substrate 600 and the pad oxide layer 612 may be etched using the hard mask layer 615 as an etch mask to form first openings 620. In some example embodiments, the first openings 620 may have a depth of about 100 Å to about 500 Å. A protecting layer 625 may be formed on side surfaces of the first openings 620.

Referring to FIG. 39, the semiconductor substrate 600 may be etched using the hard mask layer 615 as an etch mask to form second openings 630, thereby completing a vertical active substrate having a plurality of pillars. In some example embodiments, the second openings 630 may have a depth of about 500 Å to about 1,500 Å.

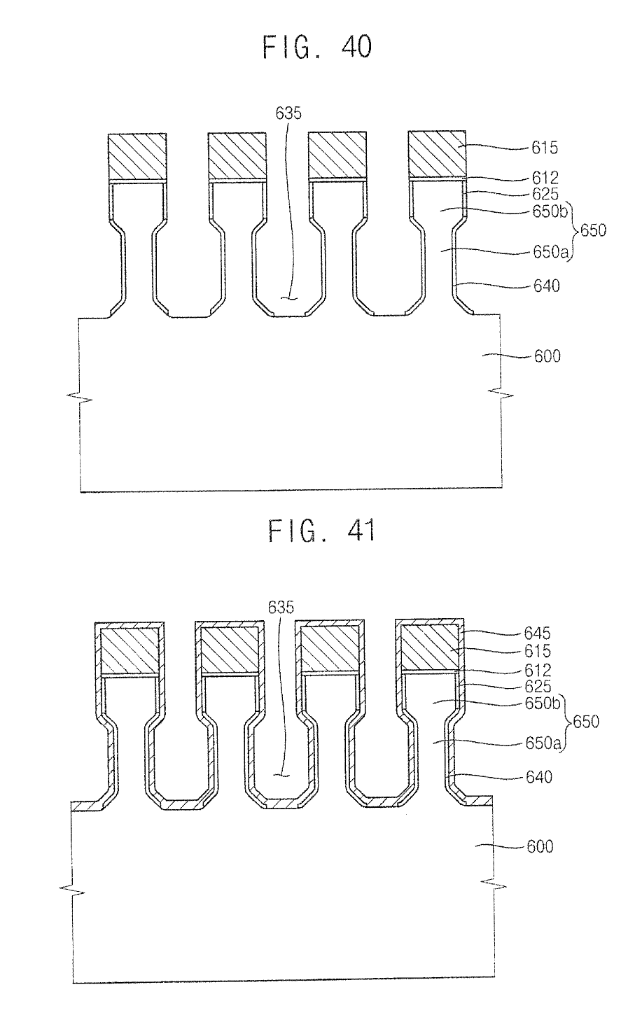

Referring to FIG. 40, portions of the semiconductor substrate 600 exposed through side surfaces of the second openings 630 may be etched using the protecting layer 625 to form third openings 635 having a wide lower portion. That is, the third openings 635 may have an upper width and a lower width greater than the upper width. Sidewalls of the vertical pillars may be wet-etched to form dumbbell-shaped pillars 650a and 650b.

Referring to FIG. 41, a gate insulating layer 640 may be formed on the dumbbell-shaped pillars 650a and 650b. In some example embodiments, the gate insulating layer 640 may include a silicon oxide layer, a hafnium oxide layer, a tantalum oxide layer, an oxide/nitride/oxide layer, etc. The gate insulating layer 640 may have a thickness of about 50 Å to about 100 Å.

In some example embodiments, in order to provide the gate insulating layer 640 with a multi-layer, a metal nitride layer 645 may be additionally formed on the gate insulating layer 640.

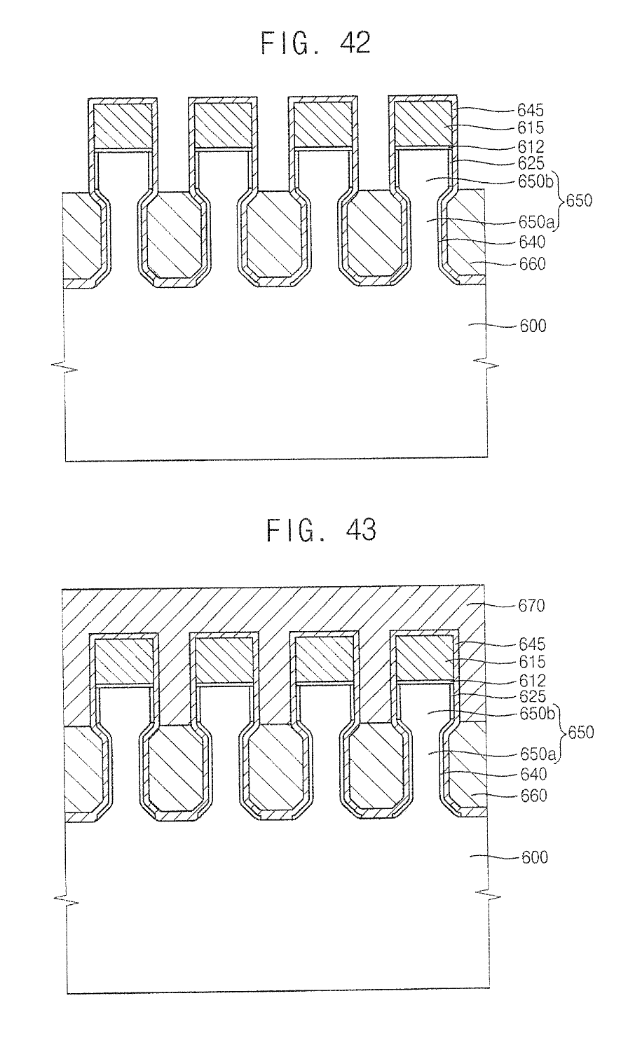

Referring to FIG. 42, a gate metal electrode layer 660 may be formed on the metal nitride layer 645. In some example embodiments, the metal electrode layer 660 may include tungsten, copper, titanium, tantalum, etc. The third holes 635 may be filled with a metal layer. The metal layer may be partially removed to form the metal electrode layer 660.

Referring to FIG. 43, a preliminary buffer layer 670 may be formed on the metal electrode layer 660 and the metal silicide layer 645 by a CVD process.

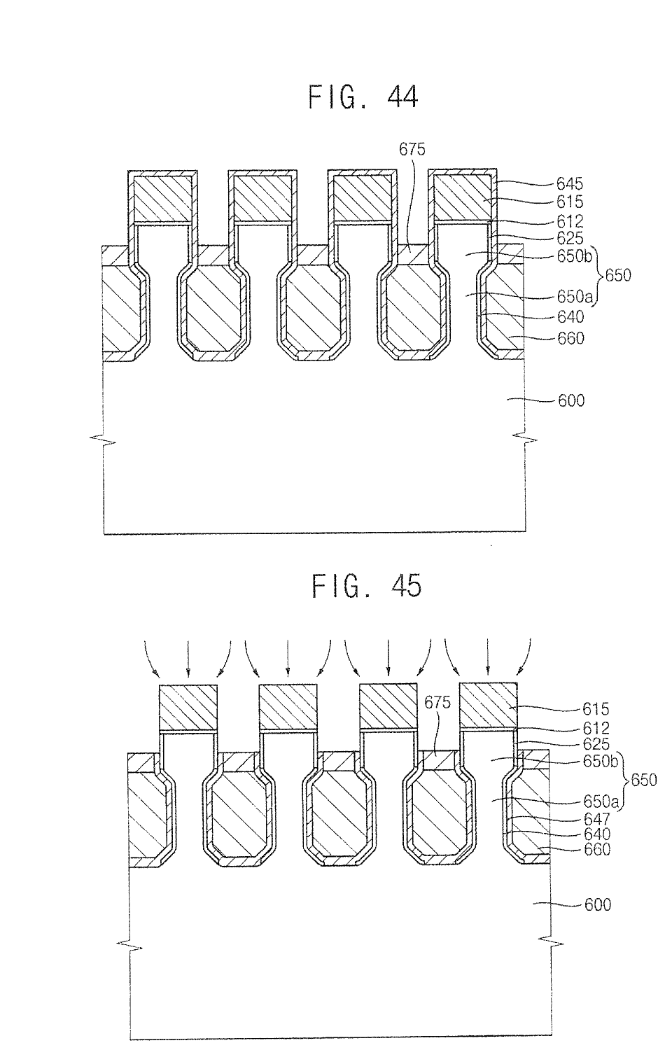

Referring to FIG. 44, the preliminary buffer layer 670 may be etched to form a buffer layer 675 on the metal electrode layer 660. Here, the buffer layer 675 may prevent damages of the metal electrode layer 660 during the gate insulating layer 645 may be removed.

Referring to FIG. 45, exposed portions of the gate insulating layer 645 may be removed.

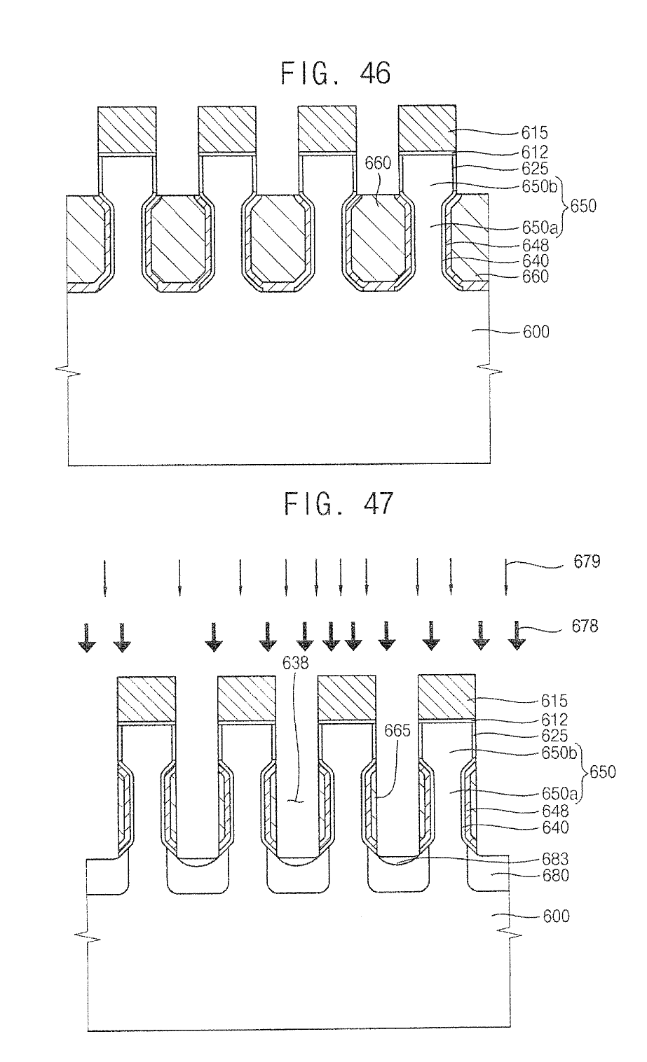

Referring to FIG. 46, the buffer layer 675 may then be removed to expose upper surfaces of the electrode layers 660.

Referring to FIG. 47, the electrode layers 660 may be etched using the hard mask layer 615 as an etch mask to form fourth openings 638. Thus, each of the electrode layers 660 may be divided into gate electrodes 665 configured to surround each of the dumbbells-shaped pillars 650a.

Portions of the semiconductor substrate 600 exposed through the fourth openings 638 may be heavily doped with impurities 678 by a first plasma doping process to form an impurity region 680. Further, the portions of the semiconductor substrate 600 may be doped using a source gas 679 including silicon such as SiH₄, SiCl₂H₂, Si₂Cl₆, Si₂H₆, Si₃H₈, etc, by a second plasma doping process. In some example embodiments, the second plasma doping process may be performed by an in-situ process in a chamber where the first plasma doping process may be performed. Further, the plasma doping process may include a glow discharge process, an RF plasma process, a microwave plasma process, etc.

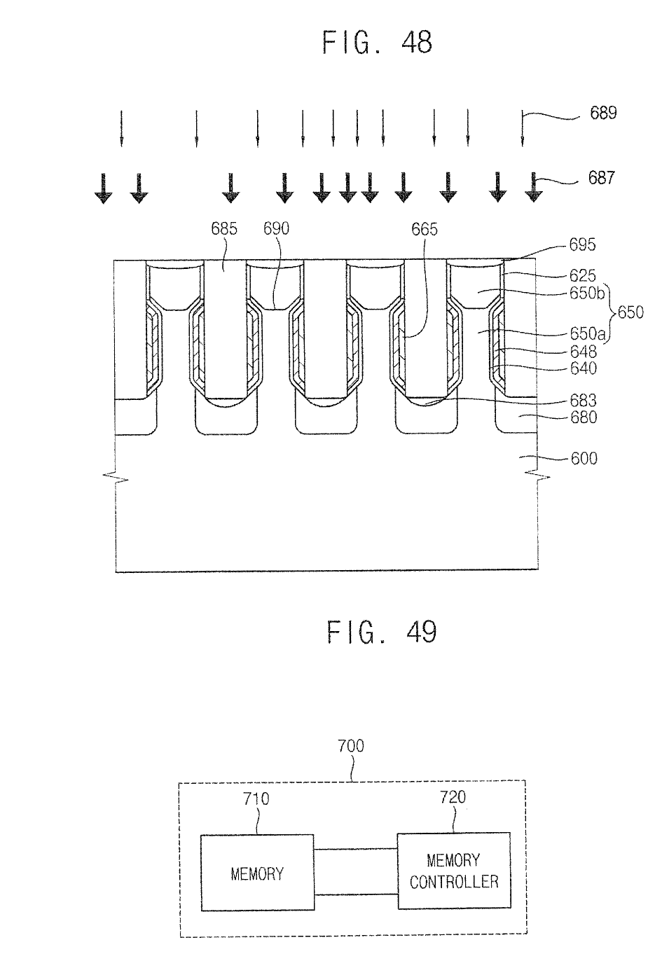

Referring to FIG. 48, after the plasma doping process, a capping layer 683 as an impurity effluence preventing layer may be formed on the impurity region 680.

In some example embodiments, the capping layer 683 may include an amorphous polysilicon layer on a single crystalline silicon layer of the semiconductor substrate 600 by a CVD process.

In some example embodiments, the capping layer 683 may have a surface concentration of the impurities and an inner concentration of the impurities higher than the surface concentration of the impurities. The capping layer 683 may be positioned higher than the semiconductor substrate 600.

Here, the polysilicon layer having little dose of the impurities in the impurity region 680 may have a large area, the impurity region 680 may have a high resistance. Thus, the capping layer 683 can be formed with a thin thickness. Additionally, a silicide layer may be formed on the capping layer 683 to reduce the resistance of the impurity region 680.

When a nickel silicide layer (not shown) may be formed on the impurity region 680, the impurity region 680 may have a very thin thickness and a low resistance.

The fourth openings 638 may then be filled with a buried layer 685. In some example embodiments, the buried layer 685 may include an oxide layer formed by a CVD process. The buried layer 685 may be planarized by an etch-back process.

The hard mask layer 615 may be removed. Impurities 687 may be implanted into the dumbbells-shaped pillars 650b to form upper source/drain regions 690 by a first plasma doping process.

The upper source/drain regions 690 may be heavily doped using a source gas 689 including silicon such as SiH₄, SiCl₂H₂, Si₂Cl₆, Si₂H₆, Si₃H₈, etc, by a second plasma doping process. In some example embodiments, the second plasma doping process may be performed by an in-situ process in a chamber where the first plasma doping process may be performed. Further, the plasma doping process may include a glow discharge process, an RF plasma process, a microwave plasma process, etc.

The vertical gate may be used for forming a capacitor, other highly integrated device, etc., by additionally providing the devices with logic circuits, memory circuits, etc.

### Example Embodiment 6

FIG. 49 is a block diagram illustrating a system including the semiconductor device in accordance with a sixth example embodiment.

Referring to FIG. 49, a system 700 may include a memory 710 and a memory controller 720 connected with the memory 710. Here, the memory 710 may include the NAND flash memory device having the capping layer in Example Embodiment 4. Alternatively, the memory 710 may include a NOR flash memory device having the capping layer.

The memory controller 720 may input control signals for controlling operations of the memory 710 into the memory 710. Here, the memory controller 720 may include the semiconductor device having the capping layer in Example Embodiment 1.

The system 700 may control data from a host or data in the memory 710 based on the control signals. The system 700 may be applied to diverse digital devices including a memory such as a digital camera, a cellular phone, etc.

### Example Embodiment 7

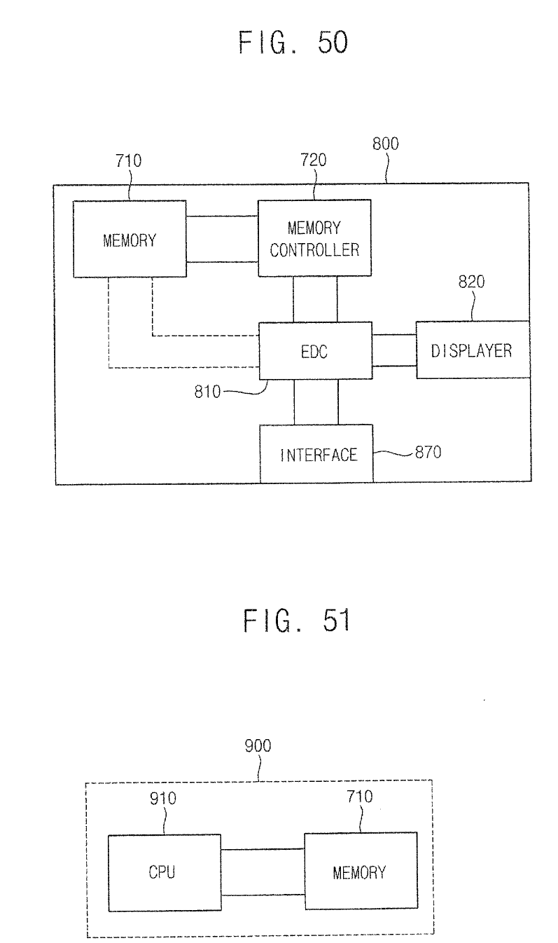

FIG. 50 is a block diagram illustrating a system including the semiconductor device in accordance with a seventh example embodiment.

Referring to FIG. 50, the system 800 may include a portable device having a memory 710 and a memory controller 720. Thus, the memory 710 may include the NAND flash memory device in Example Embodiment 4. The portable device 800 may include an MP3 player, a video player, a portable multi-media player, etc. The portable device 800 may include the memory 710, the memory controller 720, an encoder/decoder (EDC) 810, a displayer 820 and an interface 830.

Data may be inputted/outputted into/from the memory 710 through the memory controller 720 by the encoder/decoder 810. As shown dotted lines in FIG. 50, the data may be directly inputted into the memory 710. Further, the data may be outputted from the encoder/decoder 810 from the memory 710.

The encoder/decoder 810 may encode the data in the memory 710. For example, the encoder/decoder 810 may perform an MP3 encoding and a PMP encoding for storing the data in an audio player and a video player. Alternatively, the encoder/decoder 810 may perform an MPEG encoding for storing video data in the memory 710. Further, the encoder/decoder 810 may include a multi-encoder for encoding data having different types in accordance with different formats. For example, the encoder/decoder 810 may include an MP3 encoder for audio data and an MPEG encoder for video data.

In some example embodiments, the encoder/decoder 810 may include only a decoder. For example, the decoder may receive and transmit data to the memory controller 720 or the memory 710.

In some example embodiment, the encoder/decoder 810 may receive data for encoding or encoded data through the interface 830. The interface 830 may include a USB interface. The data may be outputted from the interface 830 through the memory 710.

The displayer 820 may display the data outputted from the memory 710 or decoded by the encoder/decoder 810. For example, the displayer 820 may include a speaker jack for outputting audio data, a display screen for outputting video data, etc. Here, the encoder/decoder 810 may include the semiconductor device having the capping layer in Example Embodiment 1.

### Example Embodiment 8

FIG. 51 is a block diagram illustrating a system including the semiconductor device in accordance with an eighth example embodiment.

Referring to FIG. 51, the system 900 may include the memory 710 and a CPU 910. The memory 710 may be connected with the CPU 910 in a computer system 900. The memory 710 may include the NANA flash memory device having the capping layer in Example Embodiment 4. The computer system 900 may include a notebook computer using the flash memory as a storage medium. Further, the system 900 may include other digital device including the memory 710 for storing data and controlling operations. The memory 710 may be directly connected or indirectly connected via a bus with the CPU 910.

Here, although not sufficiently Portions of the semiconductor substrate 600 exposed through the fourth openings 638 may be heavily doped with impurities 678 by a first plasma doping process to form an impurity region 680. Further, the portions of the semiconductor substrate 600 may be doped using a source gas 679 including silicon such as SiH₄, SiCl₂H₂, Si₂Cl₆, Si₂H₆, Si₃H₈, etc, by a second plasma doping process. In some example embodiments, the second plasma doping process may be performed by an in-situ process in a chamber where the first plasma doping process may be performed. Further, the plasma doping process may include a glow discharge process, an RF plasma process, a microwave plasma process, etc.

Here, although other elements may not be sufficiently depicted in FIG. 51, the depicted elements in FIG. 51 may correspond to fundamental elements of digital devices.

Above-mentioned Example embodiments may be directed to the device having impurity effluence preventing layer and the impurity region formed by the plasma doping process.

According to some example embodiments, the impurities may not be lost from the PMOS electrode layer on the semiconductor substrate. Thus, the device may have improved electrical characteristics and reliability because depletion may not be generated in the electrode layer.

Further, the heavily doped source/drain regions may have thin thickness, so that an error rate of the device may be remarkably reduced.

Furthermore, the concentration of the impurities in the impurity region, which may be formed by the plasma doping process, may not be changed. Thus, the semiconductor device having a fine structure may be readily manufactured.

Diverse devices requiring a shallow junction may be obtained due to the non-change of the impurity concentration in the impurity region. Further, the impurity region and the capping layer may be formed in the single chamber, so that productivity of the semiconductor device may be improved. As a result, a cost for manufacturing the semiconductor device may be curtailed.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1.-9. (canceled)

10. A semiconductor device comprising:
a gate insulating layer on a substrate having a first region including an NMOS device and a second region including a PMOS device;
gate electrodes formed on the gate insulating layer on the NMOS and PMOS devices; and
a capping layer over the gate electrode in the second region and absent from the first region, wherein the capping layer is configured to reduce an effluence of the impurities from an underlying impurity region into the gate electrode in the second region.

11. The semiconductor device of claim 10, wherein the capping layer comprises silicon.

12. The semiconductor device of claim 10, wherein the capping layer has a surface concentration of impurities and an inner concentration of the impurities higher than the surface concentration of the impurities.

13. The semiconductor device of claim 10, further comprising a heavily doped source/drain region between the gate electrode and the capping layer.

14. The semiconductor device of claim 10, further comprising a metal silicide layer on the capping layer.

15. A semiconductor device comprising:
a gate insulating layer on a substrate;
gate electrodes formed on the gate insulating layer;
a heavily doped source/drain region in the substrate between the gate electrodes; and
capping layers on the heavily doped source/drain region wherein the capping layers are configured to reduce an effluence of impurities from the underlying heavily doped source/drain region into the gate electrodes.

16. The semiconductor device of claim 15, wherein the capping layers comprise a polysilicon layer having a surface concentration of impurities lower than that a concentration of impurities in the heavily doped source/drain region.

17. The semiconductor device of claim 15, wherein the capping layers are positioned higher than the substrate.

18. A semiconductor device comprising:
an isolation layer in the substrate
gate electrodes formed on the substrate;
an insulating interlayer on the gate electrodes, the insulating interlayer having a contact hole between the gate electrodes;
an impurity region in the substrate exposed through the contact hole;
a capping layer on the impurity region; and
a plug on the capping layer.

19. The semiconductor device of claim 18, further comprising a capacitor on the plug.

20. (canceled)
